(19) United States
(12) Patent Application Publication
(10) Pub. No.: US 2016/0291430 A1
(43) Pub. Date: Oct. 6, 2016

(54) ARRAY SUBSTRATE AND LIQUID CRYSTAL DISPLAY DEVICE

(71) Applicants: Shanghai Tianma Micro-Electronics Co., Ltd., Shanghai (CN); Tianma Micro-Electronics Co., Ltd., Shenzhen (CN)

(72) Inventors: Yungang Sun, Shanghai (CN); Huijun Jin, Shanghai (CN); Gujun Li, Shanghai (CN)

(21) Appl. No.: 14/869,475

(22) Filed: Sep. 29, 2015

(30) Foreign Application Priority Data
Apr. 1, 2015 (CN) 201510152861.6

(51) Int. Cl. G02F 1/1362; G02F 1/1343; G02F 1/1335; G02F 1/1333; H01L 27/12; H01L 29/786

(52) U.S. Cl. CPC G02F 1/136204; H01L 27/1222; H01L 27/124; H01L 29/78669; G02F 1/133514; G02F 1/133345; G02F 1/13439

(57) ABSTRACT

An array substrate is provided, which includes: a substrate including a display region and a lead region around the display region; periphery leads disposed on a surface of the substrate in the lead region; an insulating protection layer disposed on the periphery leads; and an electrostatic protection layer disposed on the insulating protection layer. For the provided array substrate, there is no need to connect a capacitor between both ends of the ground lead to decrease static electricity, and thus saving space and effectively avoiding a breakdown of the device due to static electricity.

### CROSS REFERENCE TO RELATED APPLICATIONS

The present application claims the priority to Chinese Patent Application No. 201510152861.6, entitled “ARRAY SUBSTRATE AND LIQUID CRYSTAL DISPLAY DEVICE”, filed on Apr. 1, 2015 with the State Intellectual Property Office of the PRC, which is incorporated herein by reference in its entirety.

### FIELD OF THE INVENTION

The disclosure relates to display technologies, and in particular, to an array substrate and a liquid crystal display device.

### BACKGROUND OF THE INVENTION

Liquid crystal display is widely used to electronic products such as a computer screen, a mobile phone and a flat-panel TV due to its advantages of light and thin appearance, power saving and no radiation. The liquid crystal display includes a liquid crystal panel comprised of an array substrate, a color film substrate and liquid crystals packaged between the array substrate and the color film substrate.

At early phases, a driver chip made of a silicon wafer is externally attached to the array substrate. A gate driver IC (integrated circuit) is usually integrated in a gate line region of the array substrate at present. Specifically, an amorphous silicon gate driver (e.g. ASG driver) may be integrated with an active matrix display, that is, the gate driver IC is integrated directly in the gate line region of the array substrate, instead of externally attaching the driver chip made of the silicon wafer. With the ASG driver, the display screen becomes lighter, the reliability of the display is increased, the manufacturing process is simplified, the cost of production is reduced, and thus the integration of the liquid crystal display panel is improved.

In an existing array substrate shown in FIG. 2, periphery leads 12 are disposed in a lead region on a substrate 11, and an insulating protection layer 13 is disposed on the periphery leads 12, and a ground lead 21 and signal lines 22 are disposed in the periphery leads 12. As seen from FIG. 2, the ground lead 21 of the array substrate is a single ground lead disposed at the periphery of the array substrate; upon being powered up, the device may brake down and/or destroyed due to discharges. For an existing approach of connecting a capacitor between both ends of the ground lead 21 to decrease static electricity, large space is occupied and the cost is high.

### BRIEF SUMMARY OF THE INVENTION

In view of this, it is provided an array substrate and a liquid crystal display device in the present disclosure, to effectively resolve a problem that a device is broken down due to static electricity.

It is provided the following technical solutions in the present disclosure.

It is provided an array substrate, which includes:

a substrate including a display region and a lead region around the display region;

periphery leads disposed on a surface of the substrate and located in the lead region;

an insulating protection layer disposed on the periphery leads; and

an electrostatic protection layer disposed on the insulating protection layer.

It is further provided a liquid crystal display device in the present disclosure, which includes:

an array substrate and a color film substrate disposed opposite to the array substrate; and

a display medium disposed between the array substrate and the color film substrate,

where the array substrate is any one of the array substrates described above.

As seen from the above technical solutions, it is provided an array substrate in the present disclosure, which includes: a substrate including a display region and a lead region around the display region; periphery leads disposed on a surface of the substrate in the lead region; an insulating protection layer disposed on the periphery leads; and an electrostatic protection layer disposed on the insulating protection layer. For the array substrate according to the present disclosure, there is no need to connect a capacitor between both ends of the ground lead to decrease static electricity. As a result, space is saved and a break down of the device due to static electricity is avoided.

It is further provided a liquid crystal display device in the present disclosure, and the liquid crystal display device includes the above array substrate. Therefore, there is no need to connect a capacitor between both ends of the ground lead to decrease static electricity. As a result, space is saved and a break down of the device due to static electricity is avoided.

### BRIEF DESCRIPTION OF THE DRAWINGS

To illustrate technical solutions according to embodiments of the present disclosure or in the conventional technologies more clearly, drawings to be used in the descriptions of the conventional technologies or the embodiments are described briefly hereinafter. Apparently, the drawings described hereinafter are only for embodiments of the present disclosure, and other drawings may be obtained by those skilled in the art based on those drawings without creative efforts.

FIG. 1 is a schematic top view of an array substrate according to an embodiment of the present application;

FIG. 2 is a schematic structural diagram of a conventional array substrate;

FIG. 3 is a schematic structural diagram of an array substrate according to an embodiment of the present application;

FIG. 4 is a schematic structural diagram of an array substrate according to an embodiment of the present application;

FIG. 5 is a schematic structural diagram of an array substrate according to an embodiment of the present application;

FIG. 6 is a schematic structural diagram of an array substrate according to an embodiment of the present application;

FIG. 7 is a schematic structural diagram of an array substrate according to an embodiment of the present application;

FIG. 8 is a schematic structural diagram of an array substrate according to an embodiment of the present application;

FIG. 9 is a schematic structural diagram of an array substrate according to an embodiment of the present application;

FIG. 10 is a schematic structural diagram of an array substrate according to an embodiment of the present application;

FIG. 11 is a schematic structural diagram of an array substrate according to an embodiment of the present application;

FIG. 12 is a schematic structural diagram of an array substrate according to an embodiment of the present application;

FIG. 13 is a schematic structural diagram of an array substrate according to an embodiment of the present application; and

FIG. 14 is a schematic structural diagram of an array substrate according to an embodiment of the present application.

### DETAILED DESCRIPTION OF THE INVENTION

It is provided an array substrate according to the present disclosure. The array substrate includes: a substrate including a display region and a lead region around the display region; periphery leads disposed in the lead region on a surface of the substrate; an insulating protection layer disposed on the periphery leads; and an electrostatic protection layer disposed on the insulating protection layer. For the array substrate according to the present disclosure, there is no need to connect a capacitor between both ends of the ground lead to decrease static electricity, thereby saving space and effectively avoiding breakdown of the device due to static electricity.

It should be noted that, the electrostatic protection layer according to the embodiment may be grounded through a lead disposed additionally, or may be connected to the existing ground lead through a via hole. Arrangement of the electrostatic protection layer is not listed exhaustively, and any arrangement can be adopted as long as the electrostatic protection layer has an electrostatic protection function. Preferably, the periphery leads include a ground lead in the present embodiment, and the electrostatic protection layer is electrically connected to the ground lead through a via hole, to achieve the electrostatic protection function.

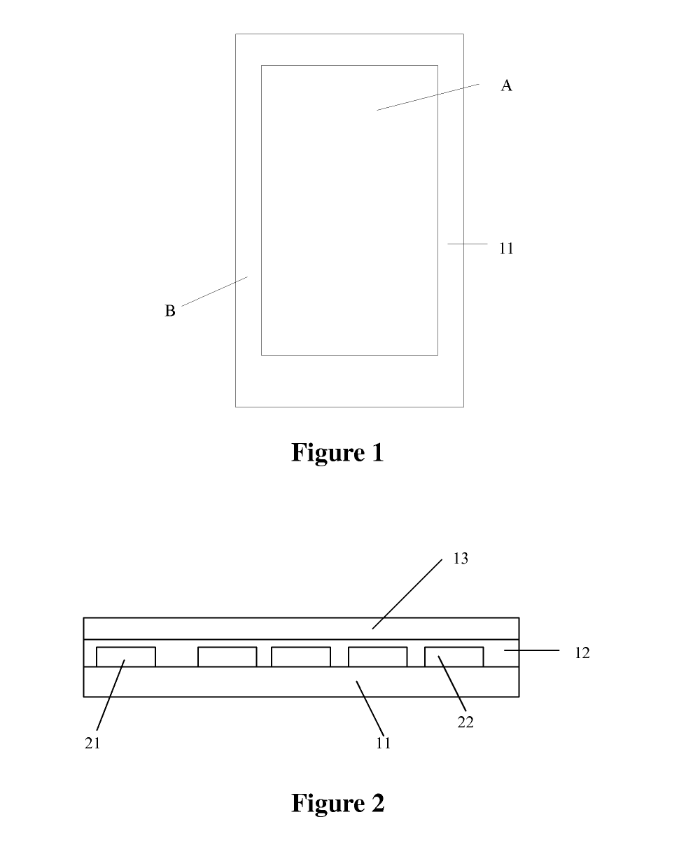

As shown in FIG. 1, it is provided an array substrate according to an embodiment. The array substrate includes a substrate 11 including a display region A and a lead region B, where the lead region B may enclose the display region A, or may be disposed at any side of the display region A. It should be noted that, FIG. 1 merely shows a top view of the array substrate, and in practice, the array substrate may include multiple layers in addition to a layer where the array substrate locates.

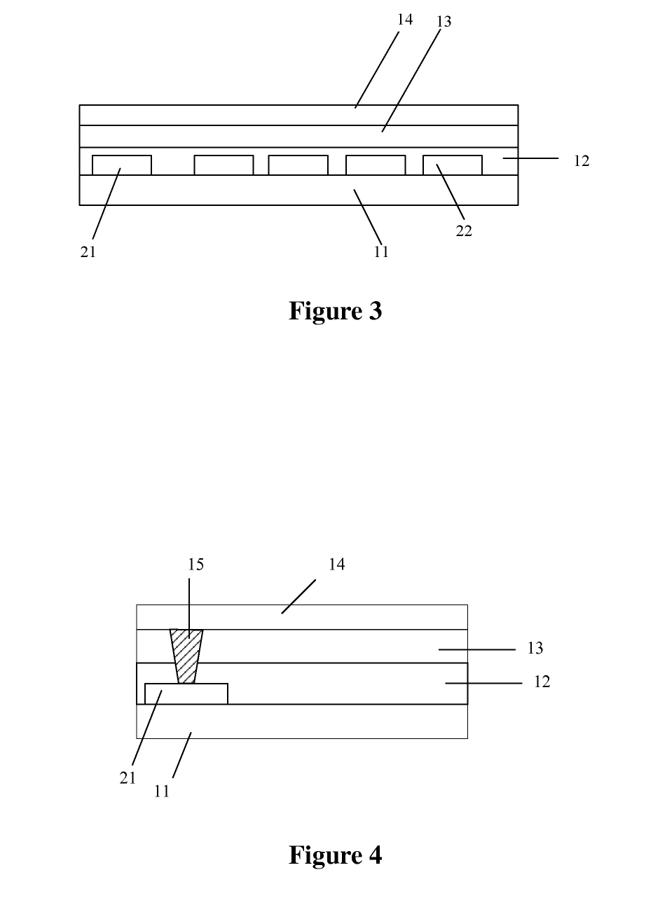

It is provided an array substrate according to an embodiment. As shown in FIG. 3, the array substrate includes: a substrate 11, periphery leads 12, an insulating protection layer 13 and an electrostatic protection layer 14.

Specifically, the substrate 11 includes a display region and a lead region around the display region; the periphery leads 12 are disposed on a surface of the substrate 11 and are located in the lead region, the insulating protection layer 13 is disposed on the periphery leads 12, and the electrostatic protection layer 14 is disposed on the insulating protection layer 13.

In the present embodiment, the electrostatic protection layer 14 is disposed on the insulating protection layer 13, and an electrostatic shielding function is enhanced through the electrostatic protection layer 14. With the array substrate according to the present disclosure, a problem in the conventional technologies that a device applying a single ground lead is prone to be broken down due to static electricity upon being powered up for a first time is resolved. Compared with the solution in the conventional technologies that a capacitor is connected between both ends of the ground lead to decrease static electricity, in the array substrate of the present disclosure, a problem that the array substrate occupies more space due to a large volume of the capacitor is avoided.

The electrostatic protection layer may have an electrostatic protection function by being grounded in the above embodiment. In other embodiments, the electrostatic protection layer may have the electrostatic protection function by being connected to the ground lead. An array substrate according to an embodiment is shown in FIG. 4 and includes a substrate 11, periphery leads 12, an insulating protection layer 13, an electrostatic protection layer 14, a ground lead 21 and a first via hole 15. The substrate 11 includes a display region and a lead region around the display region; the periphery leads 12 are disposed on a surface of the substrate 11 and are located in the lead region, the insulating protection layer 13 is disposed on the periphery leads 12, and the electrostatic protection layer 14 is disposed on the insulating protection layer 13. In the present embodiment, to occupy the space of the lead region as small as possible, the electrostatic protection layer 14 is connected to the ground lead 21 through the first via hole 15 passing through the insulating protection layer 13; and the electrostatic protection layer 14 performs electrostatic protection. For the array substrate according to the present disclosure, there is no need to connect a capacitor between both ends of the ground lead to decrease static electricity, thereby saving space and effectively avoiding breakdown of the device due to static electricity.

Based on the above embodiments, some preferred technical solutions are further provided, for example, the electrostatic protection layer 14 may be formed with either a metal layer or a transparent electrode layer, or may be formed with both of the metal layer and the transparent electrode layer.

In a case that the electrostatic protection layer is formed with both of the metal layer and the transparent electrode layer, there are the following technical solutions according to the position and connection relationship between the metal layer and the transparent electrode layer.

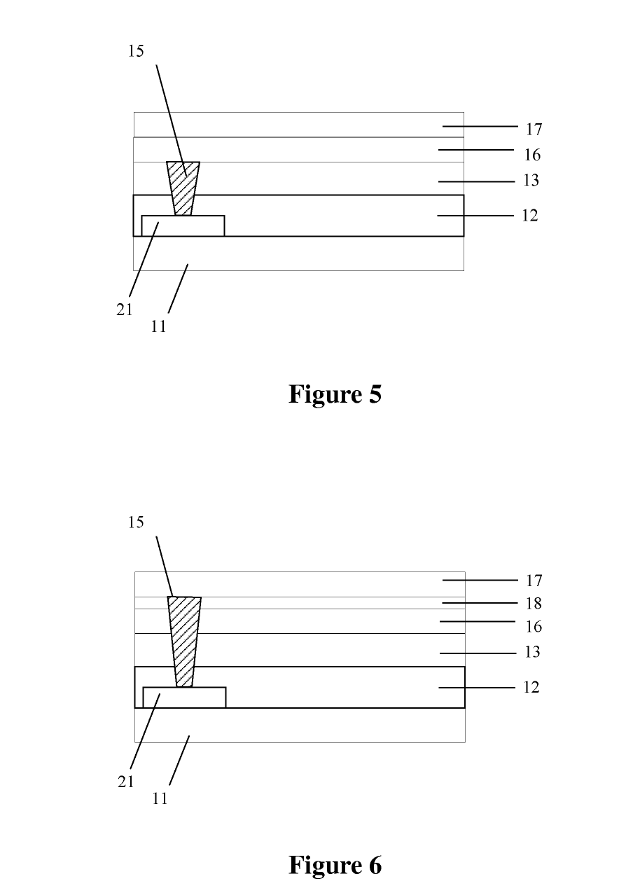

In an array substrate shown in FIG. 5, a metal layer 17 is disposed on a transparent electrode layer 16, the transparent electrode layer 16 is disposed on an insulating protection layer 13, and the transparent electrode layer 16 is connected to a ground lead 21 through a first via hole 15. In the present embodiment, the transparent electrode layer 16 is in contact with the metal layer 17 directly, and thus, the metal layer 17 is electrically connected to the ground lead 21 through the transparent electrode layer 16 and the first via hole 15.

Different from FIG. 5, in an array substrate shown in FIG. 6, an insulating layer 18 is disposed between a transparent electrode layer 16 and a metal layer 17, and a first via hole 15 passes through the insulating layer 18, the transparent electrode layer 16 and an insulating protection layer 13, such that both of the transparent electrode layer 16 and the metal layer 17 are connected to a ground lead 21 through the first via hole 15, thereby gaining electrostatic protection.

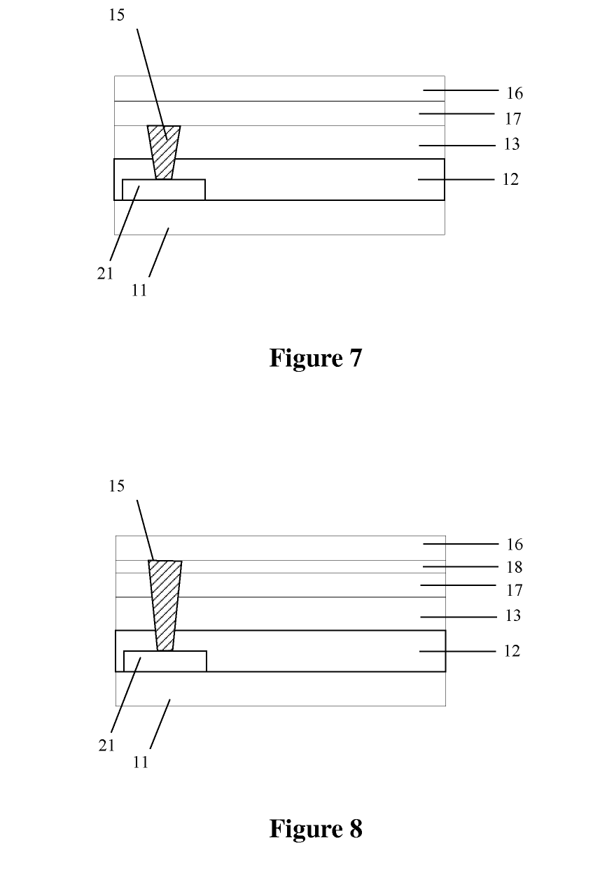

Alternatively, in an array substrate shown in FIG. 7, a transparent electrode layer 16 is disposed on a metal layer 17, the metal layer 17 is disposed on an insulating protection layer 13, and the metal layer 17 is connected to a ground lead 21 through a first via hole 15. In the present embodiment, the transparent electrode layer 16 is in contact with the metal layer 17 directly, and thus, the transparent electrode layer 16 is electrically connected to the ground lead 21 through the metal layer 17 and the first via hole 15.

Different from FIG. 7, in an array substrate shown in FIG. 8, an insulating layer 18 is disposed between a transparent electrode layer 16 and a metal layer 17, and a first via hole 15 passes through the insulating layer 18, the metal layer 17 and an insulating protection layer 13, such that both of the transparent electrode layer 16 and the metal layer 17 are connected to a ground lead 21 through the first via hole 15, thereby gaining electrostatic protection.

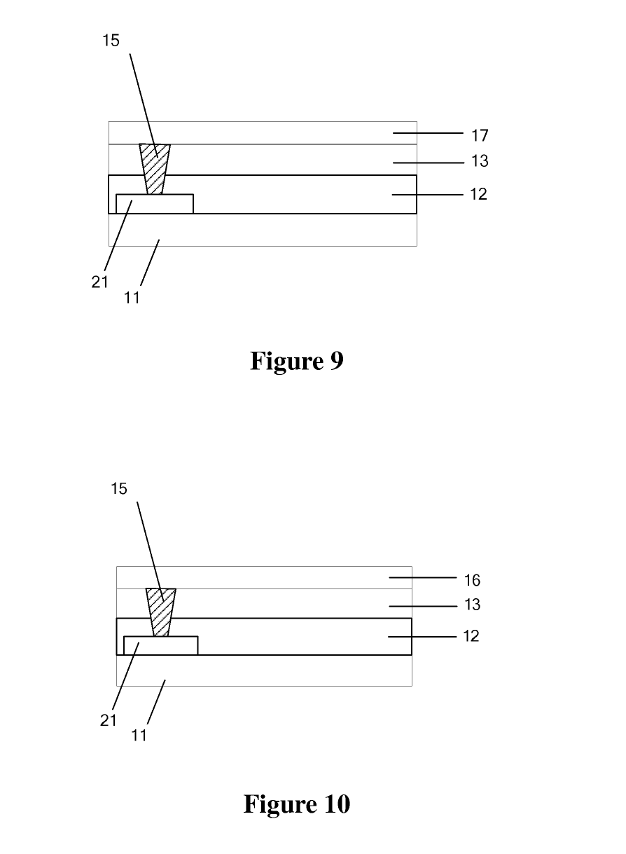

In addition the above embodiments, an electrostatic protection layer according to an embodiment may include only a metal layer 17. As shown in FIG. 9, the metal layer 17 is disposed on an insulating protection layer 13 and is connected to a ground lead 21 through a first via hole 15. Alternatively, an electrostatic protection layer according to another embodiment may include only a transparent electrode layer 16. As shown in FIG. 10, the transparent electrode layer 16 is disposed on an insulating protection layer 13 and is connected to a ground lead 21 through a first via hole 15.

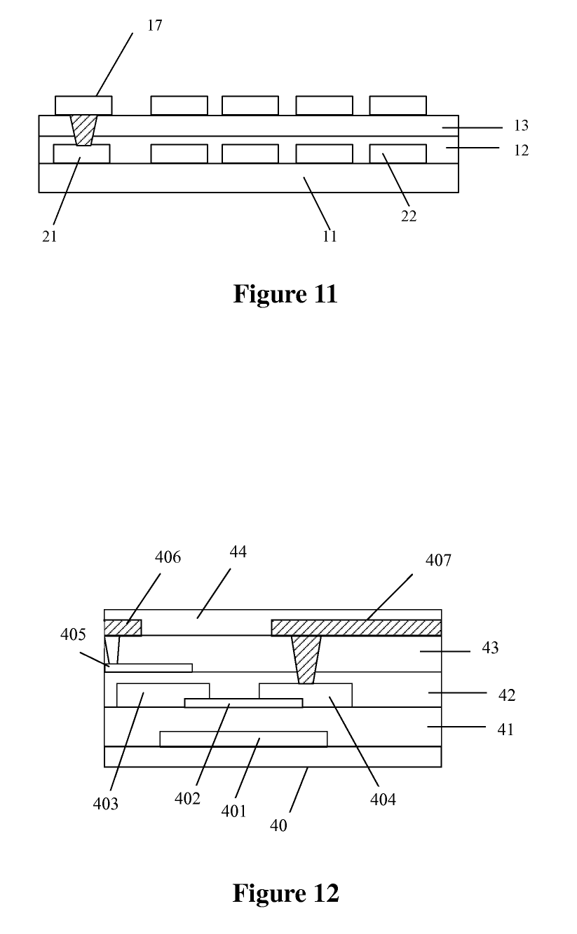

Preferably, the metal layer 17 may be a whole piece of metal layer, or may be formed by a patterning process according to signal lines. The signal lines are disposed in the lead region. For example, the metal layer 17 can be formed by patterning a first metal layer, as shown in FIG. 11. In the present embodiment, the metal layer 17 is disposed to have the same pattern as that of the signal lines 22, thereby increasing light transmittance of the lead region and thus facilitating curing the sealant in a subsequent process of manufacturing a display panel.

The metal layer may have various shapes. For example, the metal layer may include at least one metal lead, and the width of the metal lead may be less than or equal to the width of the signal line, to achieve better light transmittance.

Preferably, the transparent electrode layer may be formed in the same layer with a pixel electrode layer disposed in the display region, or may be formed in the same layer with a common electrode layer disposed in the display region.

Specifically, the common electrode layer may be only used for a display control; in this case, the common electrode layer may be a whole layer structure, or may be a continuous structure with a hollowed-out pattern. Here, the common electrode layer is only used for the display control, the common electrode layer is electrically connected to the signal lines, and the signal lines are only used to provide the common electrode layer with a display driving data signal, i.e., the signal lines here are common signal lines.

The common electrode layer may be used for both the display control and a touch control. In this case, the common electrode layer includes multiple electrode blocks; there is a one-to-one correspondence between the multiple electrode blocks and the multiple signal lines, and each of the electrode blocks is electrically connected to one of the signal lines. When the common electrode layer is used for the display control (during a display stage), each signal line is used to provide a display driving signal for the electrode block electrically connected to the signal line. When the common electrode layer is used for the touch control (during a touch stage), each signal line is used to provide a touch detection signal for the electrode block electrically connected to the signal line, and a touch detection is achieved through a self-capacitance detection under effect of a finger.

During specific manufacture, the metal layer may be formed in the same layer with a data line disposed in the display region, or may be formed in the same layer with the signal lines disposed in the display region; the transparent electrode layer may be formed in the same layer with a pixel electrode layer disposed in the display region, or may be formed in the same layer with a common electrode layer disposed in the display region. The transparent electrode layer can be arranged in various positions depending on different structures of the array substrate. Specifically, structures of the data line, the signal lines, the pixel electrode layer and the common electrode layer are shown in FIG. 12 to FIG. 14.

As shown in FIG. 12, an array substrate is provided with a thin film transistor, and the thin film transistor is disposed on a surface of a substrate 40. The thin film transistor includes: a gate electrode 401 and a gate line (not shown in FIG. 12) disposed on the surface of the substrate 40; a gate dielectric layer 41 covering the gate 401 and the gate line; and an active region 402, a source electrode 403 and a drain electrode 404 disposed on a surface of the gate dielectric layer 41. A data line (not shown in FIG. 12) connected to the source electrode 403 is disposed on the surface of the gate dielectric layer 41 and is disposed in the same layer with the source electrode 403.

In the array substrate shown in FIG. 12, the thin film transistor is disposed on the surface of the substrate 40; a first insulating layer 42 is provided covering a surface of the thin film transistor; a common electrode layer 405 is disposed on a surface of the first insulating layer 42; a second insulating layer 43 is disposed on a surface of the common electrode layer 405; a signal line 406 and a pixel electrode 407 are disposed on a surface of the second insulating layer 43; and the pixel electrode 407 is electrically connected to the drain electrode 404 of the thin film transistor through a via hole. The signal line 406 is electrically connected to, through a via hole the common electrode layer 405, when the common electrode layer 405 is used for the display control (during a display stage), each signal line is used to provide a display driving signal for the electrode block electrically connected to the signal line 406. When the common electrode layer 405 is used for the touch control (during a touch stage), each signal line 406 is used to provide a touch detection signal for the electrode block electrically connected to the signal line 406.

In an embodiment shown in FIG. 12, the signal line 406 is disposed in the same layer with the pixel electrode 407. The signal line 406 and the pixel electrode 407 can be manufactured through one conductive layer, thereby simplifying the manufacture process and reducing manufacturing costs. A third insulating layer 44 is disposed on the signal line 406 and the pixel electrode 407. A shielding electrode (not shown in FIG. 12) may be disposed on the third insulating layer 44 and is partly overlapped with the signal line 406, such that the signal line 406 is protected from electromagnetic interference.

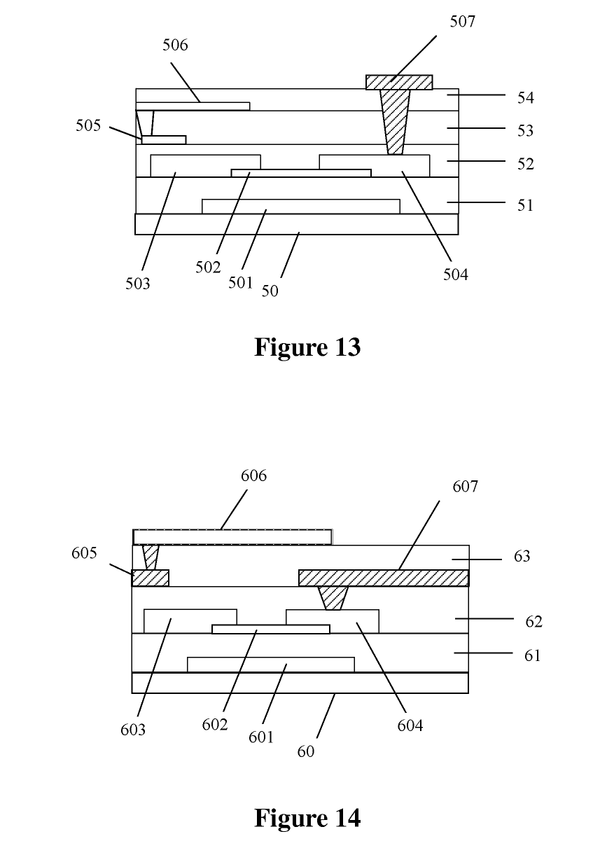

An array substrate is further provided as shown in FIG. 13, the array substrate includes a thin film transistor, and the thin film transistor is disposed on a surface of a substrate 50. The thin film transistor includes: a gate electrode 501 and a gate line (not shown in FIG. 13) disposed on the surface of the substrate 50; a gate dielectric layer 51 covering the gate electrode 501 and the gate line; and an active region 502, a source electrode 503 and a drain electrode 504 disposed on a surface of the gate dielectric layer 51. A data line (not shown in FIG. 13) connected to the source electrode 503 is disposed on the surface of the gate dielectric layer 51 and is disposed in the same layer with the source electrode 503.

In the array substrate, the thin film transistor is disposed on the surface of the substrate 50; a first insulating layer 52 is provided covering the thin film transistor; a signal line 505 is disposed on a surface of the first insulating layer 52; a second insulating layer 53 is provided covering the signal line 505; a common electrode layer 506 is disposed on a surface of the second insulating layer 53; a third insulating layer 54 is disposed on a surface of the common electrode layer 506; a pixel electrode 507 is disposed on a surface of the third insulating layer 54; and the pixel electrode 507 is electrically connected to the drain electrode 504 of the thin film transistor through a via hole. The signal line 505 is electrically connected to, through a via hole, the common electrode layer 506, when the common electrode layer 506 is used for the display control (during a display stage), each signal line is used to provide a display driving signal for the electrode block electrically connected to the signal line 505. When the common electrode layer 506 is used for the touch control (during a touch stage), each signal line 505 is used to provide a touch detection signal for the electrode block electrically connected to the signal line 505.

A shielding electrode (not shown in FIG. 13) may be disposed above the signal line 505 and is partly overlapped with the signal line 505, such that signal line 505 is protected from electromagnetic interference. Specifically, the second insulating layer 53 may be designed into a structure including two insulating layers, and the shielding electrode is disposed between the two insulating layers and is disposed above the signal line 505.

In addition, an array substrate may be disposed as shown in FIG. 14. The array substrate includes a thin film transistor, and the thin film transistor is disposed on a surface of a substrate 60. The thin film transistor includes: a gate electrode 601 and a gate line (not shown in FIG. 14) disposed on the surface of the the substrate 60; a gate dielectric layer 61 covering the gate electrode 601 and the gate line; and an active region 602, a source electrode 603 and a drain electrode 604 disposed on a surface of the gate dielectric layer 61. A data line (not shown in FIG. 14) connected to the source electrode 603 is disposed on the surface of the gate dielectric layer 61 and is disposed in the same layer with the source electrode 603.

In the array substrate shown in FIG. 14, the thin film transistor is disposed on the surface of the substrate 60; a first insulating layer 62 is providing covering the thin film transistor; a signal line 605 and a pixel electrode 607 are disposed on a surface of the first insulating layer 62, the pixel electrode 607 is electrically connected to the drain electrode 604 of the thin film transistor through a via hole; a second insulating layer 63 is disposed on surfaces of the signal line 605 and the pixel electrode 607; and a common electrode layer 606 is disposed on a surface of the second insulating layer 63.

In an embodiment shown in FIG. 14, the signal line 605 is disposed in the same layer with the pixel electrode 607. The signal line 605 and the pixel electrode 607 can be manufactured through one conductive layer, thereby simplifying the manufacturing process and reducing manufacturing costs. A shielding electrode (not shown in FIG. 14) may be disposed above the signal line 605 and is partly overlapped with the signal line 605, such that signal line 605 is protected from electromagnetic interference. Specifically, the second insulating layer 63 may be provided with a structure including two insulating layers, and the shielding electrode is disposed between the two insulating layers and is disposed above the signal line 605.

In the above embodiments, the electrostatic protection layer may be formed with a single metal layer, and the metal layer may be disposed in the same layer with the data line disposed in the display region. Or the electrostatic protection layer may be formed with a single transparent electrode layer, and the transparent electrode layer may be disposed in the same layer with either the pixel electrode disposed in the display region or the common electrode disposed in the display region. Or the electrostatic protection layer may be formed with both of the metal layer and the transparent electrode layer, where the metal layer may be disposed in the same layer with the data line disposed in the display region, and the transparent electrode layer may be disposed in the same layer with either the pixel electrode disposed in the display region or the common electrode disposed in the display region.

Preferably, the insulating protection layer is made of silicon nitride or silicon oxide.

In addition, it is further provided a liquid crystal display device according to an embodiment, which includes an array substrate, a color film substrate disposed opposite to the array substrate, and a display medium disposed between the array substrate and the color film substrate, where the array substrate is any of the array substrates described above.

In summary, it is provided an array substrate in the present disclosure; the array substrate includes: a substrate including a display region and a lead region around the display region, periphery leads disposed in the lead region on a surface of the substrate, an insulating protection layer disposed on the periphery leads, and an electrostatic protection layer disposed on the insulating protection layer. For the array substrate according to the present disclosure, there is no need to connect a capacitor between both ends of the ground lead to decrease static electricity, and thus saving space and effectively avoiding a breakdown of the device due to static electricity.

It is further provided a liquid crystal display device in the present disclosure, and the liquid crystal display device includes the above array substrate. Therefore, there is no need to connect a capacitor between both ends of the ground lead to decrease static electricity, and thus saving space and effectively avoiding a breakdown of the device due to static electricity.

The description of the embodiments disclosed herein enables those skilled in the art to implement or use the present disclosure. Numerous modifications to the embodiments are apparent to those skilled in the art, and the general principle herein can be implemented in other embodiments without deviation from the spirit or scope of the present disclosure. Therefore, the present disclosure is not limited to the embodiments described herein, but should be in accordance with the widest scope consistent with the principle and novel features disclosed herein.

What is claimed is:

1. An array substrate, comprising:
a substrate comprising a display region and a lead region, wherein the lead region surrounds the display region;
periphery leads disposed on a surface of the substrate, wherein the periphery leads are located in the lead region;
an insulating protection layer disposed on the periphery leads; and
an electrostatic protection layer disposed on the insulating protection layer.

2. The array substrate according to claim 1, wherein the periphery leads comprise a ground lead, and the electrostatic protection layer is electrically connected to the ground lead through a first via hole.

3. The array substrate according to claim 2, wherein the electrostatic protection layer is a metal layer, a transparent electrode layer, or a combination of a metal layer and a transparent electrode layer.

4. The array substrate according to claim 3, wherein the array substrate comprises the metal layer and the transparent electrode layer,
wherein the metal layer is disposed on the transparent electrode layer, and the transparent electrode layer is disposed on the insulating protection layer and is connected to the ground lead through the first via hole; or
the transparent electrode layer is disposed on the metal layer, and the metal layer is disposed on the insulating protection layer and is connected to the ground lead through the first via hole.

5. The array substrate according to claim 3, wherein the array substrate comprises the metal layer, and the metal layer is disposed on the insulating protection layer and is connected to the ground lead through the first via hole.

6. The array substrate according to claim 3, wherein the array substrate comprises the transparent electrode layer, and the transparent electrode layer is disposed on the insulating protection layer and is connected to the ground lead through the first via hole.

7. The array substrate according to claim 5, wherein a signal line is disposed in the lead region, and the metal layer is formed by a patterning process according to the signal line.

8. The array substrate according to claim 7, wherein the metal layer comprises at least one metal lead, the at least one metal lead is disposed opposite to the signal line, and the width of the at least one metal lead is less than or equal to the width of the signal line.

9. The array substrate according to claim 3, wherein the transparent electrode layer is formed in the same layer with a pixel electrode layer disposed in the display region.

10. The array substrate according to claim 3, wherein the transparent electrode layer is formed in the same layer with a common electrode layer disposed in the display region.

11. The array substrate according to claim 3, wherein the metal layer is formed in the same layer with a data line disposed in the display region.

12. The array substrate according to claim 3, wherein the metal layer is formed in the same layer with a signal line disposed in the display region.

13. The array substrate according to claim 1, wherein the insulating protection layer is made of silicon nitride or silicon oxide.

14. A liquid crystal display device, comprising:
an array substrate and a color film substrate, wherein the color film substrate is disposed opposite to the array substrate; and
a display medium disposed between the array substrate and the color film substrate, wherein the array substrate comprises:
a substrate comprising a display region and a lead region, wherein the lead region surrounds the display region;
periphery leads disposed on a surface of the substrate wherein the periphery leads are located in the lead region;
an insulating protection layer disposed on the periphery leads; and
an electrostatic protection layer disposed on the insulating protection layer.

15. The liquid crystal display device according to claim 14, wherein the periphery leads comprise a ground lead, and the electrostatic protection layer is electrically connected to the ground lead through a first via hole.

16. The liquid crystal display device according to claim 15, wherein the electrostatic protection layer is a metal layer, a transparent electrode layer, or a combination of a metal layer and a transparent electrode layer.

17. The liquid crystal display device according to claim 16, wherein the array substrate comprises the metal layer and the transparent electrode layer,
wherein the metal layer is disposed on the transparent electrode layer, and the transparent electrode layer is disposed on the insulating protection layer and is connected to the ground lead through the first via hole; or
the transparent electrode layer is disposed on the metal layer, and the metal layer is disposed on the insulating protection layer and is connected to the ground lead through the first via hole.

18. The liquid crystal display device according to claim 16, wherein the array substrate comprises the metal layer, and the metal layer is disposed on the insulating protection layer and is connected to the ground lead through the first via hole.

19. The liquid crystal display device according to claim 16, wherein the array substrate comprises the transparent electrode layer, and the transparent electrode layer is disposed on the insulating protection layer and is connected to the ground lead through the first via hole.

20. The liquid crystal display device according to claim 18, wherein a signal line is disposed in the lead region, and the metal layer is formed by a patterning process according to the signal line.
